(19) United States
(12) Patent Application Publication
(10) Pub. No.: US 2026/0114310 A1
(43) Pub. Date: Apr. 23, 2026

(54) METHOD FOR FORMING FINE-PITCH VERTICAL WIRE INTERCONNECTS

(71) Applicant: ASMPT Singapore Pte. Ltd., Singapore (SG)

(72) Inventors: Keng Yew SONG, Singapore (SG); Song Hai PAN, Chengdu City (CN); Hong Liang WANG, Chengdu City (CN); Chi Kwan PARK, Singapore (SG); Hyeon Min PARK, Singapore (SG)

(21) Appl. No.: 19/361,516

(22) Filed: Oct. 17, 2025

(30) Foreign Application Priority Data
Oct. 17, 2024 (CN) 202411457541.7

(51) Int. Cl. H01L 23/00

(52) U.S. Cl. CPC H10W 72/015; H10W 72/01551

(57) ABSTRACT

A wire bonding method for forming a vertical wire interconnect includes the steps of forming a wire bond at a bonding pad on a substrate using a wire bonding tool; moving the wire bonding tool away from the bonding pad to extend a length of the bonding wire positioned between the wire bonding tool and the wire bond; forming a weakened portion of the bonding wire by pressing a point on the length of the bonding wire between the capillary and the ball wire bond against a portion of the wire bond with the wire bonding tool, and straightening the length of the bonding wire and breaking the bonding wire at the weakened portion by moving the wire bonding tool to form a vertical wire interconnect.

### FIELD OF THE INVENTION

The invention generally relates to techniques for forming wire interconnect structures for semiconductor packages, and in particular to the formation of wire interconnect structures having vertical orientations.

### BACKGROUND

A wire bonding apparatus may be used to form bond via array (BVA) vertical wire interconnects at different locations or bonding pads on a substrate. Various methods have been used to form vertical wire interconnects on the substrate. Typically, a process for forming a vertical wire interconnect at a bonding pad on the substrate includes the following steps: conveying a bonding wire through a wire bonding tool such as a capillary, forming a weakened portion on the bonding wire before or after bonding a free end of the bonding wire onto the bonding pad and breaking the bonding wire at the weakened portion.

However, in the prior art, the weakened portion is typically formed by pressing a portion of the bonding wire against a surface elsewhere on the substrate. Consequently, these methods have low productivity because motion of the wire bonding tool over a longer distance is required for forming the weakened portion. Therefore, these methods are not suitable for applications demanding high productivity, such as memory packages and wafer-level bonding. Additionally, pressing the bonding wire against a surface of the substrate may inadvertently cause indentations, marks, or damage on the surface. Moreover, this pressing action requires empty spaces on the surface of the substrate, which space may be at a premium and/or unavailable in small packages.

It would therefore be beneficial to provide an improved method for forming vertical wire interconnects on the substrate while avoiding the aforesaid shortcomings.

### SUMMARY OF THE INVENTION

It is thus an object of the invention to seek to provide a wire bonding method for forming a vertical wire interconnect on a substrate which overcomes at least one of the aforementioned problems of the prior art.

According to a first aspect of the present invention, there is provided method for forming a vertical wire interconnect. The method includes the following steps: forming a ball wire bond at a bonding pad on a substrate with a capillary; moving the capillary away from the bonding pad to extend a length of the bonding wire positioned between the capillary and the ball wire bond; forming a weakened portion of the bonding wire by pressing a point on the length of the bonding wire between the capillary and the ball wire bond against a portion of the ball wire bond with the capillary; and straightening the length of the bonding wire and breaking the bonding wire at the weakened portion by moving the capillary to form the vertical wire interconnect.

According to a second aspect of the present invention, there is provided a wire bonding method. The method includes the following steps: forming a wire bond at a bonding pad on a substrate using a wire bonding tool; moving the wire bonding tool away from the bonding pad to extend a length of the bonding wire positioned between the wire bonding tool and the wire bond; bending the length of the bonding wire between the wire bonding tool and the wire bond to create a loop; pressing a point on the length of the bonding wire between the wire bonding tool and the wire bond adjacent to the loop against a portion of the wire bond with the wire bonding tool to form a weakened portion of the bonding wire at the point, and straightening the length of the bonding wire and breaking the bonding wire at the weakened portion by moving the wire bonding tool to form a vertical wire interconnect.

These and other features, aspects, and advantages will be better understood with regard to the description section, appended claims, and accompanying drawings.

### BRIEF DESCRIPTION OF THE DRAWINGS

Embodiments of the present invention will now be described, by way of example only, with reference to the accompanying drawings, in which:

FIG. 1A to FIG. 1J illustrate operations of a wire bonding apparatus during a wire bonding method for forming a vertical wire interconnect at a bonding pad on a substrate according to some embodiments of the invention;

FIG. 2 illustrates certain operations of the wire bonding apparatus for forming a bond ball according to some embodiments of the invention;

FIG. 3A illustrates a manipulation of the wire bonding apparatus to a position shown in FIG. 1D; FIG. 3B illustrates an alternative manner of manipulation of the wire bonding apparatus to facilitate subsequent bending of the bonding wire;

FIG. 4A illustrates operations of the wire bonding apparatus for forming a bend in the bonding wire as shown in FIG. 1E after the operations as shown in FIG. 1D according to some embodiments of the invention; FIG. 4B shows an enlarged view of a tip of a capillary of the wire bonding apparatus when forming the bend in the bonding wire as shown in FIG. 1E;

FIG. 5 shows an enlarged view of a tip of the capillary of the wire bonding apparatus when lowering the capillary to form a weakened portion at a point of the bonding wire after bending the bonding wire as shown in FIG. 1F;

FIG. 6 shows an enlarged view of the bonding wire and the tip of the capillary when the capillary causes the bonding wire to contact a neck portion of a ball wire bond according to some embodiments of the invention;

FIG. 7 shows an enlarged view of the bonding wire and the tip of the capillary when the bonding wire is pressed against a ball portion of the ball wire bond according to some embodiments of the invention; and

FIG. 8 illustrates a plurality of vertical wire interconnects formed on a substrate using the wire bonding apparatus according to the method provided in embodiments of the invention.

In the drawings, like parts are denoted by like reference numerals.

### DETAILED DESCRIPTION OF THE PREFERRED EMBODIMENTS OF THE INVENTION

Before discussing embodiments of the invention in any more detail, first an overview will be provided. To improve the productivity of the wire bonding method for forming vertical wire interconnects and enhance the quality of the vertical wire interconnects that are formed, some embodiments of the invention provide a wire bonding method in which a weakened portion of the bonding wire is formed by pressing a point on the bonding wire against a portion of a wire bond formed by bonding the bonding wire onto a bonding location on a substrate after the wire bond is formed. The bonding wire may subsequently be broken at the weakened portion to form the vertical wire interconnect.

According to some embodiments of the invention, the wire bonding method includes the following steps:
Step 10: a wire bond is formed at a bonding pad on a substrate using a wire bonding tool. In some embodiments, the wire bond includes a ball wire bond or a wedge wire bond. When the wire bond includes a ball wire bond, the wire bonding tool is in the form of a capillary.
Step 11: the wire bonding tool is moved away from the bonding pad along the bonding wire to extend a length of the bonding wire positioned between the wire bonding tool and the wire bond.

In this step, the length of the bonding wire positioned between the wire bonding tool and the wire bond may have a length less than or substantially equal to a predetermined height of a vertical wire interconnect to be formed.
Step 12: the wire bonding tool is manipulated to form a weakened portion of the bonding wire by pressing a portion or a point on the length of the bonding wire between the wire bonding tool and the wire bond against a portion of the wire bond.

In some embodiments, the wire bonding tool is operated to bend the length of the bonding wire positioned between the wire bonding tool and the wire bond, creating a loop therebetween prior to pressing the portion or the point on the bonding wire against the portion of the formed ball wire bond. The portion or point to be pressed is adjacent to the created loop.

Before bending the length of the bonding wire between the wire bonding tool and the wire bond, the wire bonding tool may be moved in a direction transverse to an axial direction of the wire bonding tool to form a kink point on the length of the bonding wire to facilitate the bending of the bonding wire and creation of the loop. The kink point may be formed between the point to be weakened and the formed wire bond.

After the kink point is formed, if the length of the bonding wire positioned between the wire bonding tool and the wire bond has a length less than the predetermined height of the vertical wire interconnect to be formed, the wire bonding tool may be moved to further extend the length of the bonding wire therebetween before creating the loop such that the portion or the point to be pressed is located at a tip of the wire bonding tool.

If the wire bond is a ball wire bond, the portion of the ball wire bond may include a ball portion or a neck portion thereof. The ball portion of the ball wire bond may include a side portion of the bond ball attached to the bonding pad, and the neck portion of the ball wire bond may include a portion of the bonding wire located above the bond ball.
Step 13: the bonding wire is straightened and broken at the weakened portion by pulling the bonding wire with the wire bonding tool to form a vertical wire interconnect.

In some embodiments of the invention, the weakened portion of the bonding wire may be formed by a two-step weakening process. In the first weakening step, the tip of the wire bonding tool is pressed against a portion or point on the bonding wire to weaken it by moving the wire bonding tool to bend the bonding wire when the bonding wire is gripped with a wire clamp that is positioned at a fixed height relative to the bonding pad, then in the second weakening step (i.e., the weakening step described in step 12 above), the wire bonding tool is further moved to create the loop of the bonding wire such that the portion or point on the bonding wire is pressed against the portion of the wire bond to further weaken it.

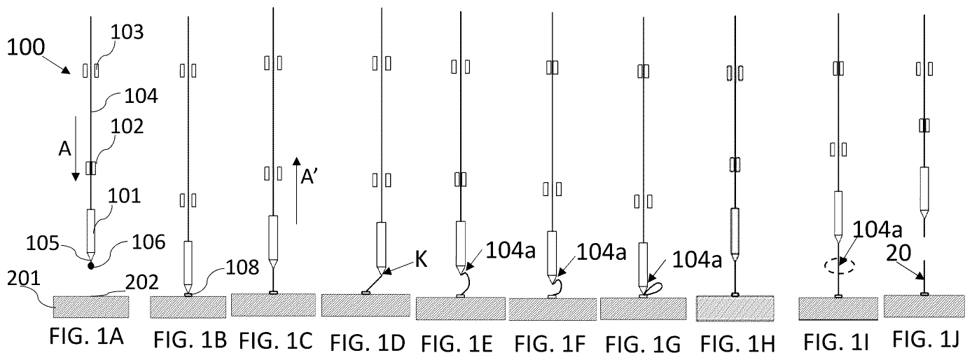

FIG. 1A to FIG. 1J illustrate operations of a wire bonding apparatus 100 during a wire bonding method for forming a vertical wire interconnect 20 at a bonding pad 202 on a substrate 201 according to some embodiments of the invention. Referring to FIG. 1A, the wire bonding apparatus 100 includes a wire holding mechanism and a capillary 101 which is positioned to axially align with the wire holding mechanism. The wire holding mechanism includes a proximal wire clamp 102 and a distal wire clamp 103 relative to the capillary 101. The two wire clamps 102 and 103 are separately operable to independently clamp or unclamp the bonding wire 104. The distal wire clamp 103 has a generally fixed height, whereas the proximal wire clamp 102 is independently displaceable along the axial direction of the bonding wire 104, as will explained in more detail below. Other components of the wire bonding apparatus 100 have been omitted to improve clarity.

FIG. 1A and FIG. 1B illustrate the operations of the wire bonding apparatus 100 for forming a ball wire bond, as described in relation to step 10. As shown in FIG. 1A, a continuous length of bonding wire 104 provided from a spool of bonding wire (not shown) passes through the distal wire clamp 103, the proximal wire clamp 102, followed by the capillary 101. A bond ball 106 is first formed at the free end of the bonding wire 104 and is located at a tip 105 of the capillary 101.

Referring to FIG. 1A, to form the bond ball 106, the bonding apparatus 100 is positioned above a bonding location where a vertical wire interconnect is to be formed, such as above the bonding pad 202 on the substrate 201. The distal wire clamp 103 is in an open state (i.e., it is not gripping the bonding wire 104) to allow the bonding wire 104 to move up and down relative to the distal wire clamp 103. Meanwhile, the proximal wire clamp 102 is in a closed state, gripping the bonding wire 104 to prevent movement of the capillary 101 along the bonding wire 104. A length of the bonding wire 104 has been passed through the capillary 101 (which is located at a preset level), such that a desired length of the bonding wire 104 protrudes from the tip 105 of the capillary 101 in order to form the bond ball 106 at the free end of the bonding wire 104 using conventional techniques such as an electric flame-off (“EFO”) torch. The bond ball 106 is located above the bonding pad 202 in readiness to be conveyed in direction A towards the bonding pad 202.

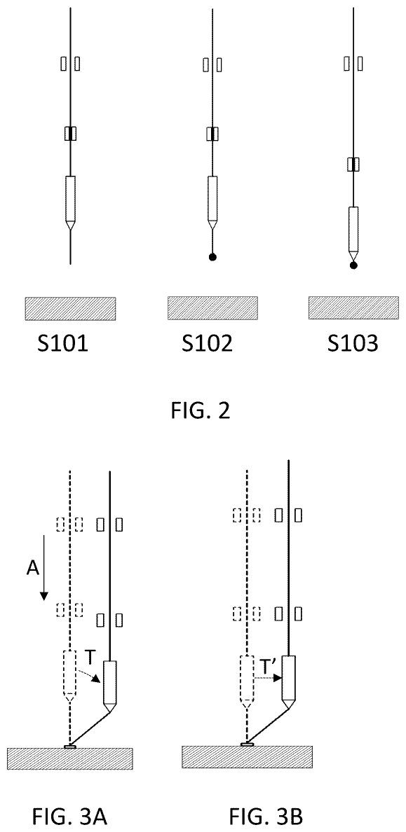

FIG. 2 illustrates certain operations of the wire bonding apparatus 100 for forming the bond ball 106 according to some embodiments of the invention. Firstly, a section of the bonding wire 104 is extended from the capillary 101 to form a wire tail with a free end (S101). Then, the bond ball 106 is formed at the free end of the bonding wire 104 using an EFO torch (S102). Thereafter, the proximate wire clamp 102 is operated to unclamp the bonding wire 104, allowing the capillary 101 together with the proximal wire clamp 102 to move down along the bonding wire 104 to position the bond ball 106 at the tip 105 of the capillary 101. Once the bond ball 106 is in place, the proximal wire clamp 102 is operated to clamp and fix a position of the bonding wire 104 (S103).

Referring to FIG. 1B, after the bond ball 106 has been formed and positioned at the tip 105 of the capillary 101, the capillary 101 and the proximal wire clamp 102 move towards the bonding pad 202 until the bond ball 106 contacts the bonding pad 202 to form a ball wire bond 108. Once the ball wire bond 108 is formed, the proximal wire clamp 102 then unclamps the bonding wire 104 to allow the capillary 101 and the proximal wire clamp 102 to move upwards along the bonding wire 104.

FIG. 1C illustrates the movement of the wire bonding apparatus 100 for positioning a length of the bonding wire 104 between the capillary 101 and the ball wire bond 108, as described in relation to step 11. Referring to FIG. 1C, the proximal wire clamp 102 together with the capillary 101 moves upwards away from the bonding pad 202 along the bonding wire 104 in direction A′ until the capillary 101 is located at a predetermined level. At this point, a required length of the bonding wire 104 would be protruding from the tip 105 of the capillary 101. The required length may be determined based on the height of the vertical wire interconnect to be formed. In some embodiments, the required length may be less than or substantially equal to the height of the vertical wire interconnect to be formed. In one example, the required length may be greater than one-third and less than two-thirds of the predetermined height of the vertical wire interconnect.

FIG. 1D to FIG. 1G illustrate operations of the wire bonding apparatus 100 for forming a weakened portion of the bonding wire 104 according to some embodiments of the invention.

Referring to FIG. 1D, the capillary 101 together with the proximal wire clamp 102 and the distal wire clamp 103 move in a direction transverse to direction A to form a kink point K on the bonding wire 104 to facilitate the subsequent creation of a loop. During this process, both the proximal wire clamp 102 and the distal wire clamp 103 remain unclamped.

FIG. 3A illustrates a manipulation of the wire bonding apparatus 100 to the position shown in FIG. 1D. As shown in FIG. 3A, the capillary 101 and the proximal wire clamp 102 move together towards the substrate 201 along a curved trajectory T such that the capillary 101, proximal and distal wire clamps 102 and 103 all translate a certain distance in a direction perpendicular to direction A. Alternatively, the capillary 101, together with the two wire clamps 102 and 103, may be translated along a straight trajectory T′ substantially perpendicular to direction A to facilitate subsequent bending of the bonding wire 104, as shown in FIG. 3B.

In these embodiments of the invention, both directions A and A′ are generally parallel to the axial direction of the capillary 101.

Referring to FIG. 1E, after the operations shown in FIG. 1D, the capillary 101 moves down to lower the bonding wire 104 towards the bonding pad 202 to form a bend in the bonding wire 104 between the capillary 101 and the ball wire bond 108. The proximal wire clamp 102 is operated to grip the bonding wire 104 once the tip 105 of the capillary 101 is located at a point 104a on the bonding wire 104 where the bonding wire 104 is to be weakened.

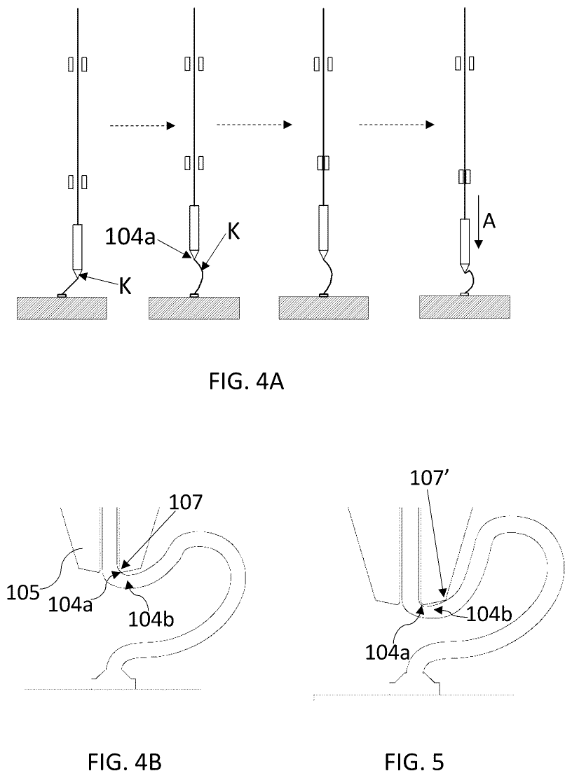

FIG. 4A illustrates the operations of the wire bonding apparatus 100 for forming the bend in the bonding wire 104 as shown in FIG. 1E after the operations as shown in FIG. 1D according to some embodiments of the invention. Referring to FIG. 4A, to form the bend in the bonding wire 104, after the kink point K is formed in FIG. 1D, the capillary 101 may move together with the proximal wire clamp 102 and the distal wire clamp 103 back to a position directly above the bonding pad 202 or the ball wire bond 108. At the same time, the length of the bonding wire 104 between the capillary 101 and the ball wire bond 108 may be further extended until the tip 105 of the capillary 101 reaches the point 104a. Then, the proximal wire clamp 102 is operated to grip the bonding wire 104 before the capillary 101 moves down along direction A to lower the bonding wire 104 towards the bonding pad 202 to form the bend in the bonding wire 104. In these embodiments, the kink point K is formed between the point 104a to be weakened and the ball wire bond 108, as shown in FIG. 4A.

It should be noted that the operations shown in FIG. 4A are for illustrative purposes only and are not intended to limit the scope of the invention. In other embodiments of the invention, various possible operations and movement paths may be used to form the bend in the bonding wire 104. For example, the capillary 101 may move upward, away from the bonding pad 202 along any direction until the point 104a is located at the tip 105 of the capillary 101, then move downward towards the bonding pad 202 to form the bend in the bonding wire 104.

FIG. 4B shows an enlarged view of the tip 105 of the capillary 101 when forming the bend in the bonding wire 104 as shown in FIG. 1E. As can be seen in FIG. 4B, an inner wall 107 of the capillary 101 is in contact with a point 104a on the bonding wire 104. The tip 105 of the capillary 101 is chamfered and shaped to define the inner wall 107 which serves to shape a fold 104b in the bonding wire 104.

Referring to FIG. 1F, after the bend in the bonding wire 104 is formed, the distal wire clamp 103 clamps onto and grips the bonding wire 104 while the proximal wire clamp 102 unclamps the bonding wire 104 to allow the capillary 101 to move down towards the bonding pad 202. This movement of the capillary 101 tensions the bonding wire 104 between the distal wire clamp 103 and the ball wire bond 108, allowing the capillary 101 to press against the point 104a of the bonding wire to weaken it.

Specifically, when the bonding wire 104 is gripped by the distal wire clamp 103, the length of the bonding wire between the distal wire clamp 103 and the ball wire bond 108 is fixed. As the proximal wire clamp 102 unclamps, it is movable together with the capillary 101 in direction A between the distal wire clamp 103 and the ball wire bond 108. The distal wire clamp 103 is operative to hold onto the bonding wire 104 while the proximal wire clamp 102 and the capillary 101 are lowered axially in direction A away from the distal wire clamp 103. As the capillary 101 is lowered, the bonding wire 104 between the distal wire clamp 103 and the ball wire bond 108 becomes tensioned, causing the capillary 101 to press against the bonding wire 104 and form a weakened portion at the point 104a.

FIG. 5 shows an enlarged view of the tip 105 of the capillary 101 when lowering the capillary 101 to weaken the point 104a of the bonding wire 104 in FIG. 1F. With the lowering of the capillary 101, the bonding wire 104 is tensioned such that the fold 104b may contact another point or portion of the tip 105 of the capillary 101. As can be seen in FIG. 5, both the inner wall 107 and an outer wall 107′ at the tip 105 of capillary 101 are contacting the bonding wire 104. This further facilitates the formation of the weakened portion at the point 104a of the bonding wire 104.

Referring to FIG. 1G, the capillary 101, together with the proximal wire clamp 102, further moves down until the bonding wire 104 protruding from the tip 105 of the capillary 101 contacts a portion of the ball wire bond 108 to create a loop. As such, a pressing force is further applied to the point 104a of the bonding wire 104 adjacent to the created loop to further weaken it.

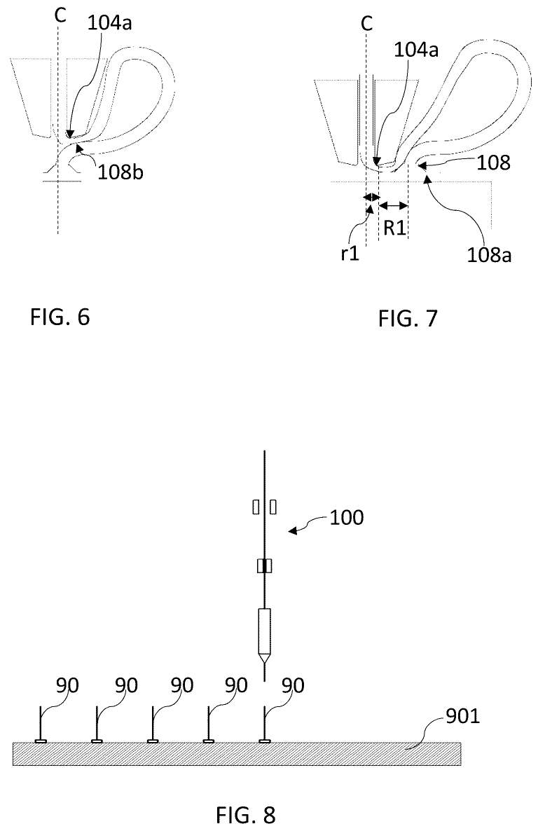

The portion of the ball wire bond 108 may include a ball portion 108a or a neck portion 108b of the ball wire bond 108. FIG. 6 shows an enlarged view of the bonding wire 104 and the tip 105 of the capillary 101 when the capillary 101 causes the bonding wire 104 to contact the neck portion 108b of the ball wire bond 108. As can be seen in FIG. 6, the point 104a is further pressed by the inner wall 107 to promote the formation of the weakened portion. When the bonding wire 104 contacts the neck portion 108b, the capillary 101 may be positioned directly above the ball portion 108a. Specifically, the central line C of the capillary 101 may be positioned to substantially align with the center line of the ball wire bond 108.

FIG. 7 shows an enlarged view of the bonding wire 104 and the tip 105 of the capillary 101 when the bonding wire 104 is pressed against a ball portion 108a of the ball wire bond 108 to compress it and increase a deformation in the weakened portion.

To avoid damaging the ball wire bond 108, the capillary 101 may be configured and operative to move within a predetermined range such that an appropriate portion of the ball wire bond 108 is pressed. The predetermined range of motion for the capillary 101 may be determined based on at least one of the following parameters: a diameter of the bonding wire 104, a size of the ball portion 108a and a size of the tip 105 of the capillary 101. In some embodiments, the capillary 101 may be configured to move within a predetermined range such that a distance between the central line C of the capillary 101 and the central line of the ball wire bond 108 is within a range from 0 to (R1+r1)/2, wherein R1 refers to the size of the ball portion 108a and r1 refers to a tip size of the capillary 101. As shown in FIG. 7, the size of the ball portion 108a may refer to the maximum diameter of the ball portion 108a. The tip size r1 of the capillary 101 refers to the distance between the central line C and the inner wall 107 of the capillary 101.

FIG. 1F and FIG. 1G illustrate the two-step weakening process for forming a weakened portion of the bonding wire 104. Specifically, FIG. 1F illustrates the first weakening step in which the point 104a of the bonding wire 104 is weakened by pressing the capillary 101 against the point 104a with the tip 105 of the capillary 101 by bending the length of the bonding wire or forming a bend between the capillary 101 and the ball wire bond 108. FIG. 1G illustrates the second weakening step in which the weakened portion formed at the point 104a of the bonding wire 104 is further weakened by pressing the point 104a against a portion of the ball wire bond 108 with the capillary 101.

It should be appreciated by a person skilled in the art that the weakened portion may be formed on a portion of the bonding wire 104 near the point 104a, rather than precisely at the point 104a using the methods provided in embodiments of the invention. For instance, the weakened portion may be formed on a portion of the fold 104b near the point 104a.

FIG. 1H to FIG. 1J illustrate the operations of the wire bonding apparatus 100 during the formation of the vertical wire interconnect 20 (i.e., step 13). The bonding wire 104 is straightened and is broken at the weakened portion by pulling the capillary 101 away from the ball wire bond 108 to form the vertical wire interconnect 20.

In FIG. 1H, the proximal wire clamp 102 is operated to grip the bonding wire 104, and the distal wire clamp 103 now unclamps the bonding wire 104 to allow the proximal wire clamp 102 and the capillary 101 to move together in direction A′ away from the bonding pad 202 to straighten the bonding wire 104 which is connected to the ball wire bond 108.

In FIG. 1I the proximal wire clamp 102 unclamps the bonding wire 104 and the distal wire clamp 103 now grips the bonding wire 104 to allow the capillary 101 and the proximal wire clamp 102 to move up along the bonding wire 104 such that the weakened portion at the point 104a is located between the tip 105 of the capillary 101 and the ball wire bond 108. The length of bonding wire 104 between the tip 105 and the ball wire bond 108 is determined based on a desired tail length to be left after the bonding wire 104 is broken at the weakened portion.

In FIG. 1J, the proximal wire clamp 102 is closed to clamp the bonding wire 104 and the distal wire clamp 103 is opened to unclamp the bonding wire 104. Thereafter, the capillary 101 together with the proximal wire clamp 102 are raised in direction A′. This movement causes the bonding wire 104 to break at the weakened portion at the point 104a, leaving a desired length of the bonding wire 104 in place in a vertical orientation to form the vertical wire interconnect 20.

FIG. 8 illustrates a plurality of vertical wire interconnects 90 formed on a substrate 901 using the wire bonding apparatus 100 according to the method provided in embodiments of the invention. The operations of the wire bonding apparatus 100 as shown in FIG. 1A to FIG. 1J are repeated for forming adjacent vertical wire interconnects 90 at different positions or bonding pads on the substrate 901.

Using the method provided by embodiments of the invention, the wire bonding cycle time is more than 50% faster than prior art methods, thereby significantly improving the productivity and efficiency of the wire bonding process for forming vertical wire interconnects. Furthermore, the proposed method provides a highly flexible solution for fine pitch devices in system in package (SIP) and memory packages, and is capable of ensuring higher productivity as compared with the prior art.

Although the present invention has been described in considerable detail with reference to certain embodiments, other embodiments are possible. For example, the method provided by embodiment of the invention may also be used for forming vertical wire interconnects by other bonding approaches. Accordingly, the wire bond formed by the wire bonding apparatus may include a wire bonding tool for forming other types of wire bonds formed on the bonding pad. Therefore, the spirit and scope of the appended claims should not be limited to the description of the embodiments contained herein.

1. A method for forming a vertical wire interconnect, comprising the steps of:
forming a ball wire bond at a bonding pad on a substrate with a capillary;
moving the capillary away from the bonding pad to extend a length of the bonding wire positioned between the capillary and the ball wire bond;
forming a weakened portion of the bonding wire by pressing a point on the length of the bonding wire between the capillary and the ball wire bond against a portion of the ball wire bond with the capillary; and
straightening the length of the bonding wire and breaking the bonding wire at the weakened portion by moving the capillary in a direction away from the ball wire bond to form the vertical wire interconnect.

2. The method according to claim 1, wherein the step of forming a ball wire bond comprises: forming a bond ball at a free end of the bonding wire and bonding the bond ball to the bonding pad to form a ball wire bond using the capillary.

3. The method according to claim 1, wherein the step of forming the weakened portion comprises: bending the length of the bonding wire between the capillary and the ball wire bond to create a loop between the capillary and the ball wire bond prior to pressing the point on the length of the bonding wire adjacent the loop against the portion of the formed ball wire bond.

4. The method according to claim 3, wherein the step of forming the weakened portion further comprises: weakening the point on the length of the bonding wire between the capillary and the ball wire bond by pressing the capillary against the point with a tip of the capillary by bending the length of the bonding wire.

5. The method according to claim 4, wherein the step of bending the length of the bonding wire comprises: moving the capillary in a direction transverse to an axial direction of the capillary to form a kink point on the length of the bonding wire between the capillary and the ball wire bond to facilitate the bending.

6. The method according to claim 5, wherein the kink point is formed between the point to be weakened and the ball wire bond.

7. The method according to claim 5, wherein the step of bending the length of the bonding wire further comprises: moving the capillary to locate the point to be weakened at the tip of the capillary after the kink point is formed, and moving the capillary towards the ball wire bond to bend the length of the bonding wire.

8. The method according to claim 7, wherein the step of moving the capillary comprises: moving the capillary to a position directly above the ball wire bond.

9. The method according to claim 4, wherein the step of bending the length of the bonding wire comprises: gripping the bonding wire with a first wire clamp that is positioned at a fixed height relative to the bonding pad, and moving the capillary towards the ball wire bond to form a fold at the point on the length of the bonding wire around the tip of the capillary to weaken the point on the length of the bonding wire.

10. The method according to claim 9, further comprising: gripping the bonding wire with a second wire clamp to prevent movement of the capillary along the bonding wire when bending the length of the bonding wire before the first wire clamp clamps the bonding wire, wherein the second wire clamp is located closer to the wire bonding tool than the first wire clamp.

11. The method according to claim 10, further comprising: unclamping the second wire clamp after the first wire clamp is operated to clamp the bonding wire for weakening the point on the length of the bonding wire.

12. The method according to claim 1, wherein the portion of the ball wire bond includes a ball portion of the ball wire bond or a neck portion of the ball wire bond.

13. The method according to claim 12, further comprising: determining a range of motion for the capillary when pressing the point against the portion of the ball wire bond based on at least one parameter including: a diameter of the bonding wire, a size of the ball portion of the ball wire bond and a size of a tip of the capillary.

14. A wire bonding method, comprising the steps of:
forming a wire bond at a bonding pad on a substrate using a wire bonding tool;
moving the wire bonding tool away from the bonding pad to extend a length of the bonding wire positioned between the wire bonding tool and the wire bond;
bending the length of the bonding wire between the wire bonding tool and the wire bond to create a loop;
pressing a point on the length of the bonding wire between the wire bonding tool and the wire bond adjacent to the loop against a portion of the wire bond with the wire bonding tool to form a weakened portion of the bonding wire at the point, and
straightening the length of the bonding wire and breaking the bonding wire at the weakened portion by moving the wire bonding tool to form a vertical wire interconnect.
